(19) United States
(12) Patent Application Publication
(10) Pub. No.: US 2019/0179181 A1
(43) Pub. Date: Jun. 13, 2019

(54) LIQUID CRYSTAL DISPLAY DEVICE

(71) Applicant: Sharp Kabushiki Kaisha, Osaka (JP)

(72) Inventors: Seiichi UCHIDA, Sakai City (JP); Kuniaki OKADA, Sakai City (JP)

(21) Appl. No.: 16/210,053

(22) Filed: Dec. 5, 2018

(30) Foreign Application Priority Data
Dec. 8, 2017 (JP) 2017-235867

(51) Int. Cl. G02F 1/1337; G02F 1/1362; G02F 1/1335; G02F 1/1339; G02F 1/1343; H01L 27/12

(52) U.S. Cl. CPC G02F 1/1337; G02F 1/136286; G02F 1/133512; G02F 1/133514; G02F 2201/123; G02F 1/134309; H01L 27/1225; G02F 2201/121; G02F 1/13394

(57) ABSTRACT

A first substrate of a liquid crystal display device includes a plurality of gate lines, a plurality of source lines, a TFT and a pixel electrode provided in each of the pixels, a first insulating layer covering the source lines, and a first alignment film. A second substrate includes a light-blocking layer, a plurality of columnar spacers, and a second alignment film. A drain electrode of the TFT is a transparent drain electrode formed from the same transparent conductive film as the pixel electrode. Each columnar spacer is arranged in an intersecting region where one of the gate lines and one of the source lines intersect with each other. The first insulating layer has first openings formed in the intersecting regions corresponding to at least some columnar spacers. A surface of the first substrate on a side of the liquid crystal layer has depressed portions that are defined by the first openings. Distal end portions of the at least some columnar spacers are located in the depressed portions.

### BACKGROUND

### 1. Technical Field

The present invention relates to a liquid crystal display device, and more particularly to a liquid crystal display device including oxide semiconductor TFTs.

### 2. Description of the Related Art

An active matrix substrate used in a liquid crystal display device, or the like, includes a switching element such as a thin film transistor (hereinafter, “TFT”) for each pixel. As such a switching element, a TFT using an oxide semiconductor layer as the active layer (hereinafter referred to as an “oxide semiconductor TFT”) is known in the art. Japanese Laid-Open Patent Publication No. 2012-134475 discloses a liquid crystal display device using InGaZnO (an oxide composed of indium, gallium and zinc) in the active layer of the TFT.

Oxide semiconductor TFTs are capable of operating faster than amorphous silicon TFTs. Since oxide semiconductor films are formed by a simpler process than polycrystalline silicon films, it can be applied to devices that require large areas. Thus, oxide semiconductor TFTs have had high expectations as high-performance active elements that can be manufactured while suppressing the number of manufacturing steps and the manufacturing cost.

Since an oxide semiconductor has a high mobility, it is possible to realize a level of performance that is greater than or equal to that of an amorphous silicon TFT even when the size is reduced relative to a conventional amorphous silicon TFT. Thus, when an active matrix substrate of a liquid crystal display device is manufactured by using an oxide semiconductor TFT, it is possible to reduce the area ratio of the TFT relative to the area of the pixel, thereby improving the pixel aperture ratio. Thus, it is possible to produce bright display even when the amount of light of the backlight is reduced, thereby realizing a low power consumption.

Since oxide semiconductor TFTs have desirable off-leak characteristics, it is possible to use a mode of operation with which images are displayed while reducing the image rewrite frequency. For example, when displaying a still image, they can be operated so that the image data is rewritten once per second. Such a driving method is called pause drive or low-frequency drive, and it is possible to significantly reduce the power consumption of the liquid crystal display device.

### SUMMARY

As described above, although it is possible to improve the aperture ratio when an oxide semiconductor TFT is used, as compared with a case where an amorphous silicon TFT is used, the definition of the liquid crystal display device has recently been further improved, and there is a demand for further improving the aperture ratio.

However, it is difficult for the following reason to further improve the aperture ratio of a liquid crystal display device having oxide semiconductor TFTs.

An ordinary liquid crystal display device is provided with a columnar spacer that defines the thickness of the liquid crystal layer (referred to as the “cell gap”). An area around the columnar spacer is shaded by a black matrix (light-blocking layer) because it may lead to light leakage because of liquid crystal molecules being aligned in a direction different from the intended alignment direction. Note however that if the panel warps after the active matrix substrate and the counter substrate are attached together, the columnar spacer may possibly shift sideways and scratch the alignment film, leading to light leakage. Therefore, the width (size) of a portion of the black matrix that shades the area around the columnar spacer is set to be relatively large. This hinders the attempt to improve the aperture ratio.

The present invention has been made in view of these problems, and an object thereof is to improve the aperture ratio of a liquid crystal display device including oxide semiconductor TFTs.

A liquid crystal display device according to an embodiment of the present invention is a liquid crystal display device, including: a first substrate; a second substrate opposing the first substrate; and a liquid crystal layer provided between the first substrate and the second substrate, wherein: the liquid crystal display device includes a plurality of pixels arranged in a matrix pattern having rows and columns; the first substrate includes a plurality of gate lines each extending in a row direction, a plurality of source lines each extending in a column direction, a TFT provided in each of the pixels, a pixel electrode provided in each of the pixels, a first insulating layer covering the source lines, and a first alignment film provided so as to be in contact with the liquid crystal layer; the second substrate includes a light-blocking layer arranged so as to be aligned with the gate lines and the source lines, a plurality of columnar spacers defining a thickness of the liquid crystal layer, and a second alignment film provided so as to be in contact with the liquid crystal layer; the TFT includes a gate electrode, a source electrode, a drain electrode, and an oxide semiconductor layer; the pixel electrode is electrically connected to the drain electrode of the TFT; the drain electrode is a transparent drain electrode formed from the same transparent conductive film as the pixel electrode; each of the columnar spacers is arranged in an intersecting region where one of the gate lines and one of the source lines intersect with each other; the first insulating layer has first openings formed in the intersecting regions corresponding to at least some of the columnar spacers; a surface of the first substrate on a side of the liquid crystal layer has depressed portions that are defined by the first openings; and distal end portions of the at least some of the columnar spacers are located in the depressed portions.

In one embodiment, the columnar spacers include a plurality of main spacers having a first height, and a plurality of sub spacers having a second height that is smaller than the first height; and the at least some of the columnar spacers are the main spacers.

In one embodiment, the first insulating layer has an additional first opening formed in each of the intersecting regions corresponding to the sub spacers; a surface of the first substrate on a side of the liquid crystal layer has an additional depressed portion defined by the additional first opening; and distal end portions of the sub spacers are aligned with the additional depressed portions.

In one embodiment, the oxide semiconductor layer is provided on the gate electrode with a gate insulating layer interposed therebetween; the oxide semiconductor layer and the source electrode are covered by the first insulating layer; the first insulating layer has a second opening through which a portion of the oxide semiconductor layer is exposed; and the transparent drain electrode is connected to the oxide semiconductor layer through the second opening.

A liquid crystal display device according to another embodiment of the present invention is a liquid crystal display device including: a first substrate; a second substrate opposing the first substrate; and a liquid crystal layer provided between the first substrate and the second substrate, wherein: the liquid crystal display device includes a plurality of pixels arranged in a matrix pattern having rows and columns; the first substrate includes a plurality of gate lines each extending in a row direction, a plurality of source lines each extending in a column direction, a TFT provided in each of the pixels, a pixel electrode provided in each of the pixels, a plurality of columnar spacers defining a thickness of the liquid crystal layer, and a first alignment film provided so as to be in contact with the liquid crystal layer; the second substrate includes a light-blocking layer arranged so as to be aligned with the gate lines and the source lines, a color filter layer, a flattening layer covering the color filter layer, and a second alignment film provided so as to be in contact with the liquid crystal layer; the TFT includes a gate electrode, a source electrode, a drain electrode, and an oxide semiconductor layer; the pixel electrode is electrically connected to the drain electrode of the TFT; the drain electrode is a transparent drain electrode formed from the same transparent conductive film as the pixel electrode; each of the columnar spacers is arranged in an intersecting region where one of the gate lines and one of the source lines intersect with each other; the flattening layer has depressed portions formed in the intersecting regions corresponding to at least some of the columnar spacers; and distal end portions of the at least some of the columnar spacers are located in the depressed portions.

In one embodiment, the columnar spacers include a plurality of main spacers having a first height, and a plurality of sub spacers having a second height that is smaller than the first height; and the at least some of the columnar spacers are the main spacers.

In one embodiment, the flattening layer has additional depressed portions formed in the intersecting regions corresponding to sub spacers; and distal end portions of the sub spacers are aligned with the additional depressed portions.

In one embodiment, the first substrate further includes a first insulating layer covering the source lines; the oxide semiconductor layer is provided on the gate electrode with a gate insulating layer interposed therebetween; the oxide semiconductor layer and the source electrode are covered by the first insulating layer; the first insulating layer has an opening through which a portion of the oxide semiconductor layer is exposed; and the transparent drain electrode is connected to the oxide semiconductor layer through the opening.

A liquid crystal display device according to still another embodiment of the present invention is a liquid crystal display device including: a first substrate; a second substrate opposing the first substrate; and a liquid crystal layer provided between the first substrate and the second substrate, wherein: the liquid crystal display device includes a plurality of pixels arranged in a matrix pattern having rows and columns; the first substrate includes a plurality of gate lines each extending in a row direction, a plurality of source lines each extending in a column direction, a TFT provided in each of the pixels, a pixel electrode provided in each of the pixels, a first insulating layer provided on the source lines, and a first alignment film provided so as to be in contact with the liquid crystal layer; the second substrate includes a light-blocking layer arranged so as to be aligned with the gate lines and the source lines, a plurality of columnar spacers defining a thickness of the liquid crystal layer, and a second alignment film provided so as to be in contact with the liquid crystal layer; the TFT includes a gate electrode, a source electrode, a drain electrode, and an oxide semiconductor layer; the pixel electrode is electrically connected to the drain electrode of the TFT; the drain electrode is a transparent drain electrode formed from the same transparent conductive film as the pixel electrode; each of the columnar spacers is located between two adjacent ones of the source lines and is arranged so as to be aligned with one of the gate lines while not aligned with the source electrodes; the first insulating layer includes a first portion that covers the source lines and the source electrodes, and a second portion that does not cover the source lines and the source electrodes and that is depressed relative to the first portion; a surface of the first substrate on a side of the liquid crystal layer has a depressed portion that is defined by the second portion of the first insulating layer and is provided at each of positions corresponding to at least some of the columnar spacers; and distal end portions of the at least some of the columnar spacers are located in the depressed portions.

In one embodiment, the columnar spacers include a plurality of main spacers having a first height, and a plurality of sub spacers having a second height that is smaller than the first height; and the at least some of the columnar spacers are the main spacers.

In one embodiment, a surface of the first substrate on a side of the liquid crystal layer has an additional depressed portion that is defined by the second portion of the first insulating layer and is provided at each of positions corresponding to the sub spacers; and distal end portions of the sub spacers are aligned with the additional depressed portions.

In one embodiment, the oxide semiconductor layer is provided on the gate electrode with a gate insulating layer interposed therebetween; the oxide semiconductor layer is covered by the first insulating layer; the first insulating layer has an opening through which a portion of the oxide semiconductor layer is exposed; and the transparent drain electrode is connected to the oxide semiconductor layer through the opening.

In one embodiment, the first substrate further includes a second insulating layer covering the pixel electrode, and a common electrode provided on the second insulating layer.

In one embodiment, the oxide semiconductor layer includes an In—Ga—Zn—O-based semiconductor.

In one embodiment, the In—Ga—Zn—O-based semiconductor includes a crystalline portion.

According to embodiments of the present invention, it is possible to improve the aperture ratio of liquid crystal display devices having oxide semiconductor TFTs.

### BRIEF DESCRIPTION OF THE DRAWINGS

FIG. 1 is a plan view schematically showing a liquid crystal display device 100 according to an embodiment of the present invention.

FIGS. 2A and 2B are cross-sectional views schematically showing the liquid crystal display device 100, taken along line 2A-2A′ and line 2B-2B′, respectively, of FIG. 1.

FIGS. 3A and 3B are a plan view and a cross-sectional view, respectively, showing a liquid crystal display device 900 of a reference example, wherein FIG. 3B shows a cross section taken along line 3B-3B′ of FIG. 3A.

FIG. 4 is a plan view schematically showing a liquid crystal display device 200 according to an embodiment of the present invention.

FIGS. 5A and 5B are cross-sectional views schematically showing the liquid crystal display device 200, taken along line 5A-5A′ and line 5B-5B′, respectively, of FIG. 4.

FIG. 6 is a plan view schematically showing a liquid crystal display device 300 according to an embodiment of the present invention.

FIG. 7 is a cross-sectional view schematically showing the liquid crystal display device 300, taken along line 7A-7A′ of FIG. 6.

FIG. 8 is a plan view schematically showing a liquid crystal display device 400 according to an embodiment of the present invention.

FIGS. 9A and 9B are cross-sectional views schematically showing the liquid crystal display device 400, taken along line 9A-9A′ and line 9B-9B′, respectively, of FIG. 8.

FIG. 10 is a plan view schematically showing a liquid crystal display device 500 according to an embodiment of the present invention.

FIG. 11 is a cross-sectional view schematically showing the liquid crystal display device 500, taken along line 11A-11A′ of FIG. 10.

FIG. 12 is a plan view schematically showing a liquid crystal display device 600 according to an embodiment of the present invention.

FIGS. 13A and 13B are cross-sectional views schematically showing the liquid crystal display device 600, taken along line 13A-13A′ and line 13B-13B′, respectively, of FIG. 12.

### DETAILED DESCRIPTION

Embodiments of the present invention will now be described with reference to the drawings. Note that the present invention is not limited to the following embodiments.

### Embodiment 1

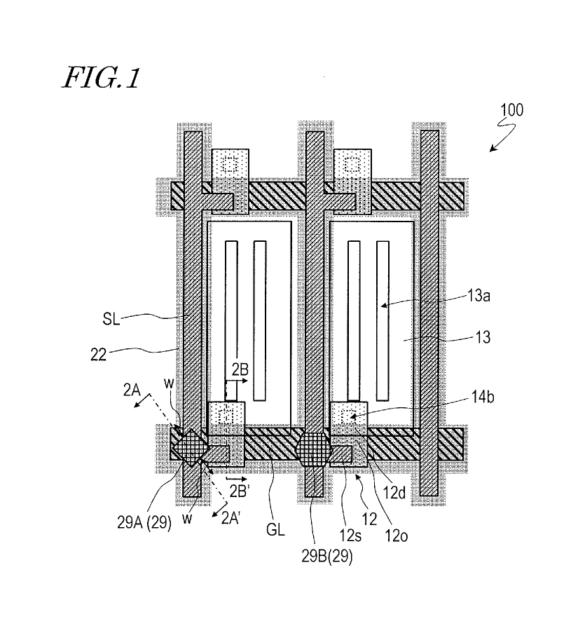

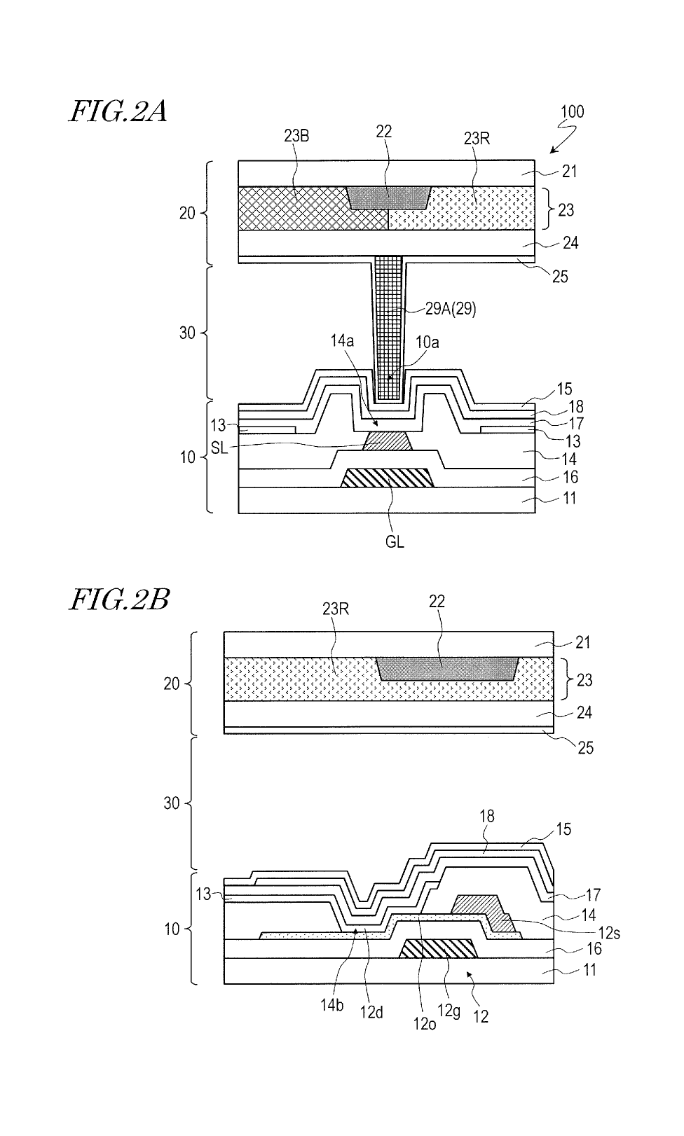

Referring to FIGS. 1, 2A and 2B, a liquid crystal display device 100 of the present embodiment will be described. FIG. 1 is a plan view schematically showing the liquid crystal display device 100. FIGS. 2A and 2B are cross-sectional views schematically showing the liquid crystal display device 100, taken alone line 2A-2A′ and line 2B-2B′, respectively, of FIG. 1.

As shown in FIGS. 2A and 2B, the liquid crystal display device 100 includes an active matrix substrate (hereinafter referred to as a “TFT substrate”) 10, a counter substrate (referred to also as a “color filter substrate”) 20 opposing the TFT substrate 10, and a liquid crystal layer 30 provided between the TFT substrate 10 and the counter substrate 20. The liquid crystal display device 100 includes a plurality of pixels. The pixels are arranged in a matrix pattern having rows and columns. FIG. 1 shows two pixels that are adjacent to each other along the row direction. The plurality of pixels typically include red pixels displaying red, green pixels displaying green, and blue pixels displaying blue.

As shown in FIGS. 1, 2A and 2B, the TFT substrate 10 includes a plurality of gate lines GL each extending in the row direction, a plurality of source lines SL each extending in the column direction, a thin film transistor (TFT) 12 provided for each pixel, a pixel electrode 13 provided for each pixel, a first insulating layer (interlayer insulating layer) 14 covering the source lines SL, and a first alignment film 15 provided so as to be in contact with the liquid crystal layer 30. The components of the TFT substrate 10 are supported on an insulative transparent substrate (e.g., a glass substrate or a plastic substrate) 11.

Each of the gate lines GL supplies a gate signal (scanning signal) to the TFT 12 of a corresponding pixel. Each of the source lines SL supplies a source signal (display signal) to the TFT 12 of a corresponding pixel.

The TFT 12 includes a gate electrode 12g, a source electrode 12s, a drain electrode 12d, and an oxide semiconductor layer 12o. That is, the TFT 12 is an oxide semiconductor TFT. In the illustrated example, the TFT 12 has a bottom gate structure, wherein the oxide semiconductor layer 12o is provided on the gate electrode 12g with a gate insulating layer 16 interposed therebetween.

The gate electrode 12g of the TFT 12 is electrically connected to a corresponding gate line GL. In the illustrated example, a region of the gate lines GL that overlaps with the oxide semiconductor layer 12o functions as the gate electrode 12g.

The source electrode 12s of the TFT 12 is electrically connected to a corresponding source line SL. In the illustrated example, the source electrode 12s is extended so as to branch off from the source line SL. The source electrode 12s and the oxide semiconductor layer 12o are covered by the first insulating layer 14.

The drain electrode 12d of the TFT 12 is electrically connected to the pixel electrode 13. In the present embodiment, the drain electrode 12d is a transparent drain electrode that is formed from the same transparent conductive film as the pixel electrode 13. It can be said that a portion of the pixel electrode 13 functions as the drain electrode 12d. The first insulating layer 14 has an opening (a region where the insulating material is removed) 14b, through which a portion of the oxide semiconductor layer 12o is exposed, and the transparent drain electrode 12d is connected to the oxide semiconductor layer 12o through the opening 14b. That is, the opening 14b is a pixel contact hole.

Since the liquid crystal display device 100 of the present embodiment displays images in the FFS (Fringe-Field Switching) mode, the pixel electrode 13 includes at least one (two in the illustrated example) slit 13a. A second insulating layer (dielectric layer) 17 is formed so as to cover the pixel electrode 13, and a common electrode 18 is provided on the second insulating layer 17.

The first alignment film 15 is provided so as to cover the common electrode 18. The first alignment film 15 is located at the outermost level of the TFT substrate 10 on the liquid crystal layer 30 side.

The counter substrate 20 includes a light-blocking layer (black matrix) 22 arranged so as to be aligned with the gate lines GL and the source lines SL, a plurality of columnar spacers 29 that defines the thickness of the liquid crystal layer 30, and a second alignment film 25 provided so as to be in contact with the liquid crystal layer 30. The light-blocking layer 22 is generally lattice-shaped so as to be aligned with the gate lines GL and the source lines SL. The components of the counter substrate 20 are supported on an insulative transparent substrate (e.g., a glass substrate or a plastic substrate) 21.

The counter substrate 20 further includes a color filter layer 23 and a flattening layer 24 covering the color filter layer 23. The color filter layer 23 typically includes a red color filter 23R, a green color filter 23G and a blue color filter 23B (the green color filter 23G is not shown in FIGS. 2A and 2B).

Each columnar spacer 29 is arranged in an intersecting region where one of the gate lines GL and one of the source lines SL intersect with each other. Note that there is no need that the columnar spacers 29 are arranged in all of the intersecting regions. The arrangement density of the columnar spacers 29 is determined appropriately based on the size, the application, etc., of the liquid crystal display device 100.

In the present embodiment, the columnar spacers 29 include a plurality of main spacers 29A having a first height, and a plurality of sub spacers 29B having a second height that is smaller than the first height. That is, the columnar spacers 29 include two types of spacers of different heights (the main spacer 29A and the sub spacer 29B).

In the present embodiment, as shown in FIG. 2A, the first insulating layer 14 includes openings (regions where the insulating material is removed) 14a formed in the intersecting region each corresponding to the main spacer 29A. Note that of the openings 14a and 14b of the first insulating layer 14, the openings 14a formed in the intersecting regions will be refereed to as “first openings”, and the openings 14b through which portions of the oxide semiconductor layer 12o are exposed (pixel contact holes) will be referred to as “second openings”.

The surface of the TFT substrate 10 on the liquid crystal layer 30 side has a depressed portion 10a that is defined by the first opening 14a of the first insulating layer 14 (i.e., that reflects the shape of the first opening 14a). The distal end portion of each main spacer 29A is located in the depressed portion 10a.

The liquid crystal display device 100 of the present embodiment can be manufactured as follows, for example.

First, a method for producing the counter substrate 20 will be described.

First, a light-blocking film (e.g., a light-blocking resin film having a thickness of 1000 nm) is deposited on a transparent substrate (e.g., a glass substrate) 21, and the light-blocking film is patterned by a photolithography process to an intended shape, thus forming the lattice-shaped light-blocking layer 22. Note that the material of the light-blocking layer 22 is not limited to a resin material but may be a metal material.

Next, the red color filter 23R, the green color filter 23G and the blue color filter 23B are successively formed in regions corresponding to red pixels, green pixels and blue pixels, thus forming the color filter layer 23. The materials of the red color filter 23R, the green color filter 23G and the blue color filter 23B may be colored photosensitive resin materials, for example.

Then, a flattening layer (overcoat layer) 24 is formed so as to cover the color filter layer 23. The material of the flattening layer 24 is a transparent resin material, for example.

Then, the columnar spacers 29 are formed at predetermined positions. The columnar spacers 29 are formed from a photosensitive resin material, for example. Finally, the second alignment film 25 is formed on the flattening layer 24, thus obtaining the counter substrate 20.

Next, a method for producing the TFT substrate 10 will be described.

First, a conductive film is deposited on a transparent substrate (e.g., a glass substrate) 11, and the conductive film is patterned by a photolithography process to an intended shape, thus forming the gate electrodes 12g and the gate lines GL. The gate electrodes 12g and the gate lines GL have a layered structure in which a TaN layer having a thickness of 30 nm and a W layer having a thickness of 300 nm are layered in this order, for example.

Next, the gate insulating layer 16 is formed so as to cover the gate electrodes 12g and the gate lines GL. The gate insulating layer 16 has a layered structure in which an SiNx layer having a thickness of 325 nm and an SiO₂ layer having a thickness of 50 nm are layered in this order, for example.

Then, an oxide semiconductor film is deposited on the gate insulating layer 16, and the oxide semiconductor film is patterned by a photolithography process to an intended shape, thus forming the oxide semiconductor layer 12o. The oxide semiconductor layer 12o is an In—Ga—Zn—O-based semiconductor layer having a thickness of 50 nm, for example.

Then, a conductive film is deposited, and the conductive film is patterned to an intended shape by a photolithography process, thereby forming the source electrode 12s and the source line SL. For example, the source electrode 12s and the source line SL have a layered structure including a Ti layer having a thickness of 30 nm, an Al layer having a thickness of 200 nm, and a Ti layer having a thickness of 100 nm, which are layered in this order.

Next, the first insulating layer 14 is formed so as to cover the oxide semiconductor layer 12o, the source electrode 12s and the source line SL. For example, the first insulating layer 14 has a layered structure including an SiO₂ layer having a thickness of 300 nm and an SiNx layer having a thickness of 100 nm, which are layered in this order. The first opening 14a and the second opening 14b are formed by a photolithography process in a predetermined region of the first insulating layer 14.

Then, a transparent conductive film is deposited on the first insulating layer 14, and the transparent conductive film is patterned to an intended shape by a photolithography process, thereby forming the pixel electrode 13. The pixel electrode 13 is an IZO layer having a thickness of 100 nm, for example.

Next, the second insulating layer 17 is formed so as to cover the pixel electrode 13. The second insulating layer 17 is an SiN layer having a thickness of 100 nm, for example.

Then, a transparent conductive film is deposited on the second insulating layer 17, and the transparent conductive film is patterned to an intended shape by a photolithography process, thereby forming the common electrode 18. The common electrode 18 is an IZO layer having a thickness of 100 nm, for example. Then, the first alignment film 15 is formed across the entire surface so as to cover the common electrode 18, thereby obtaining the TFT substrate 10.

The TFT substrate 10 and the counter substrate 20, which are produced as described above, are attached together, and a liquid crystal material is injected into the gap therebetween, thereby forming the liquid crystal layer 30. Then, the obtained structure is severed into individual panels, thus completing the liquid crystal display device 100.

With the liquid crystal display device 100 of the present embodiment having the structure described above, it is possible to improve the aperture ratio as compared with conventional liquid crystal display devices including oxide semiconductor TFTs. The reason for this will now be described by way of comparison with a liquid crystal display device of a reference example.

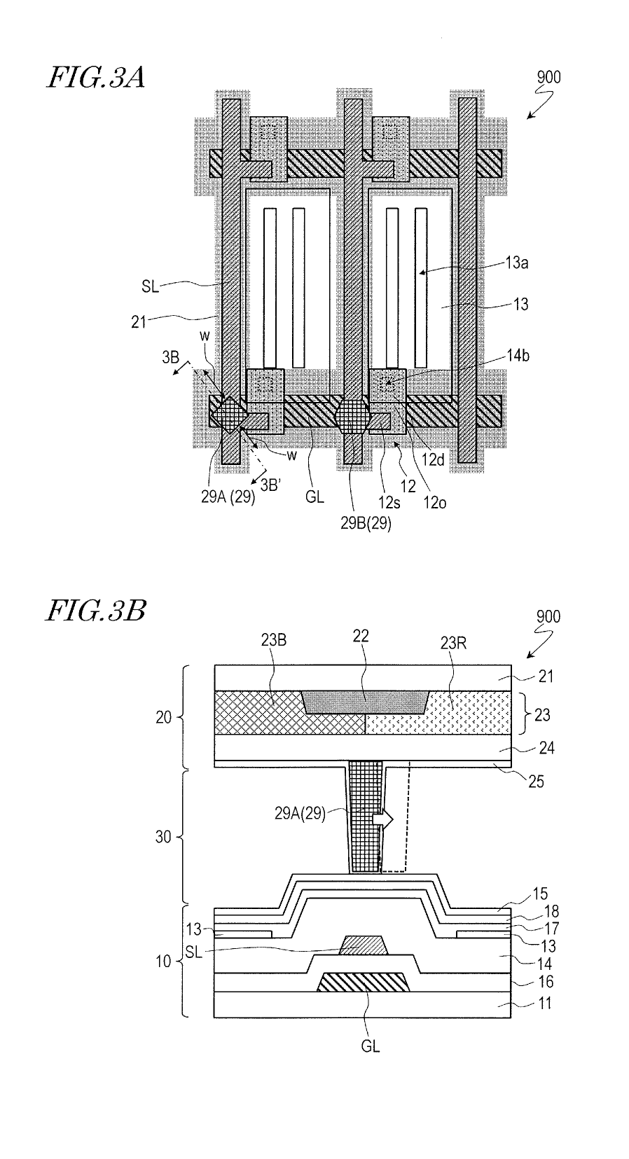

FIGS. 3A and 3B are a plan view and a cross-sectional view, respectively, showing a liquid crystal display device 900 of a reference example. FIG. 3B shows a cross section taken along line 3B-3B′ of FIG. 3A. The liquid crystal display device 900 of the reference example is different from the liquid crystal display device 100 of the present embodiment in that the first insulating layer 14 has no openings in intersecting regions corresponding to the main spacers 29A. Therefore, with the liquid crystal display device 900 of the reference example, the distal end portions of the main spacers 29A are in contact with the flat portion on the surface of the TFT substrate 10.

With the liquid crystal display device 900 of the reference example, if the panel warps after the TFT substrate 10 and the counter substrate 20 are attached together, the main spacer 29A may possibly shift sideways (as indicated by a dotted line in FIG. 3B). If the main spacer 29A shifts, it scratches the first alignment film 15, which leads to light leakage in such a portion, thus lowering the display quality. Thus, with the liquid crystal display device 900 of the reference example, there is a need to prevent light leakage for the case where the first alignment film 15 is scratched by setting large the width (size) of a portion of the light-blocking layer 22 for shading an area around the columnar spacer 29.

In contrast, with the liquid crystal display device 100 of the present embodiment, the first insulating layer 14 has the first opening 14a in each of the intersecting regions corresponding to the main spacers 29A, and the surface of the TFT substrate 10 on the liquid crystal layer 30 side has the depressed portion 10a that is defined by the first opening 14a of the first insulating layer 14. Then, the distal end portion of each main spacer 29A is located in the depressed portion 10a (i.e., fitted into the depressed portion 10a). Therefore, it is possible to prevent the main spacer 29A from shifting sideways and scratching the first alignment film 15. Thus, it is possible to set small the width (size) of a portion of the light-blocking layer 22 for shading an area around the columnar spacer 29, thereby improving the aperture ratio.

Note that on the surface of the TFT substrate 10 on the liquid crystal layer 30 side, there are also depressed portions defined by the second openings (contact holes) 14b, in addition to the depressed portions 10a defined by the first openings 14a of the first insulating layer 14. Thus, one may consider a configuration in which the main spacers 29A are fitted into those depressed portions (i.e., the main spacers 29A are aligned with the contact holes). With such configuration, however, there is a need to shade areas around the contact holes, and it is no longer possible to use the areas around the contact holes for displaying images.

In the present embodiment, the columnar spacers 29 are arranged at positions other than the contact holes, and a structure using the transparent drain electrode 12d as the connection structure to the TFT 12 of the pixel electrode 13 (referred to as the “transparent contact structure”) is employed. Thus, it is possible to also use the areas around the contact holes for displaying images, and it is possible to further improve the aperture ratio.

Table 1 below shows an approximate calculation of the pixel aperture ratio for the liquid crystal display device 900 of the reference example and that for the liquid crystal display device 100 of the present embodiment. The pixel size was 20 μm×60 μm, the width (the width along the row direction) of the light-blocking layer 22 on the source line SL was 7 μm, and the diameter of the columnar spacer 29 was 9 μm. The width w of a portion for shading the area around the main spacer 29A (the distance from the outer edge of the main spacer 29A to the outer edge of the light-blocking layer 22: see FIG. 1, FIG. 3A) is about 8 μm with the liquid crystal display device 900 of the reference example, but it can be reduced to about 4 μm with the liquid crystal display device 100 of the present embodiment. As can be seen from Table 1, the aperture ratio, which was 38% for the liquid crystal display device 900 of the reference example, was improved to 47% with the liquid crystal display device 100 of the present embodiment.

TABLE 1
Aperture ratio comparison
(pixel size: 20 μm × 60 μm)

| | Aperture ratio |
|---|---|
| Reference Example | 38% |
| Embodiment 1 | 47% |

Note that although there is no particular limitation on the size of the first opening 14a of the first insulating layer 14 as long as the distal end portion of the main spacer 29A is located in the depressed portion 10a, it is preferred that the size is determined taking into consideration possible misalignments so that the main spacer 29A is located in the depressed portion 10a even if there is a misalignment between the TFT substrate 10 and the counter substrate 20 when attached together. Since the misalignment is typically about ±2 to 3 μm, the diameter of the first opening 14a is preferably larger than the diameter of the main spacer 29A by about 6 μm (3 μm on each side).

While the TFT 12 of a bottom gate structure is illustrated herein, TFTs provided in the liquid crystal display device according to an embodiment of the present invention are not limited to those of a bottom gate structure but may be those of a top gate structure. Even with a TFT (oxide semiconductor TFT) of a top gate structure, it is possible to realize a transparent contact structure by using, as the drain electrode, a transparent drain electrode formed from the same transparent conductive film as the pixel electrode (i.e., making a portion of the pixel electrode function as the drain electrode).

### Embodiment 2

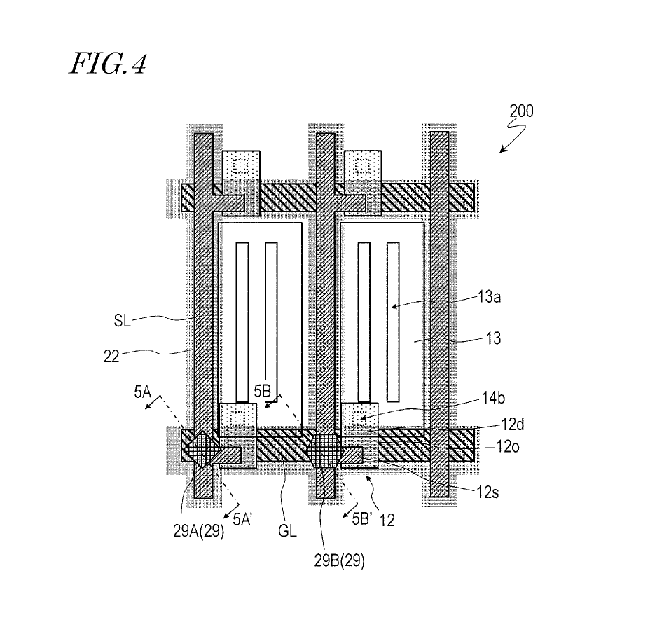

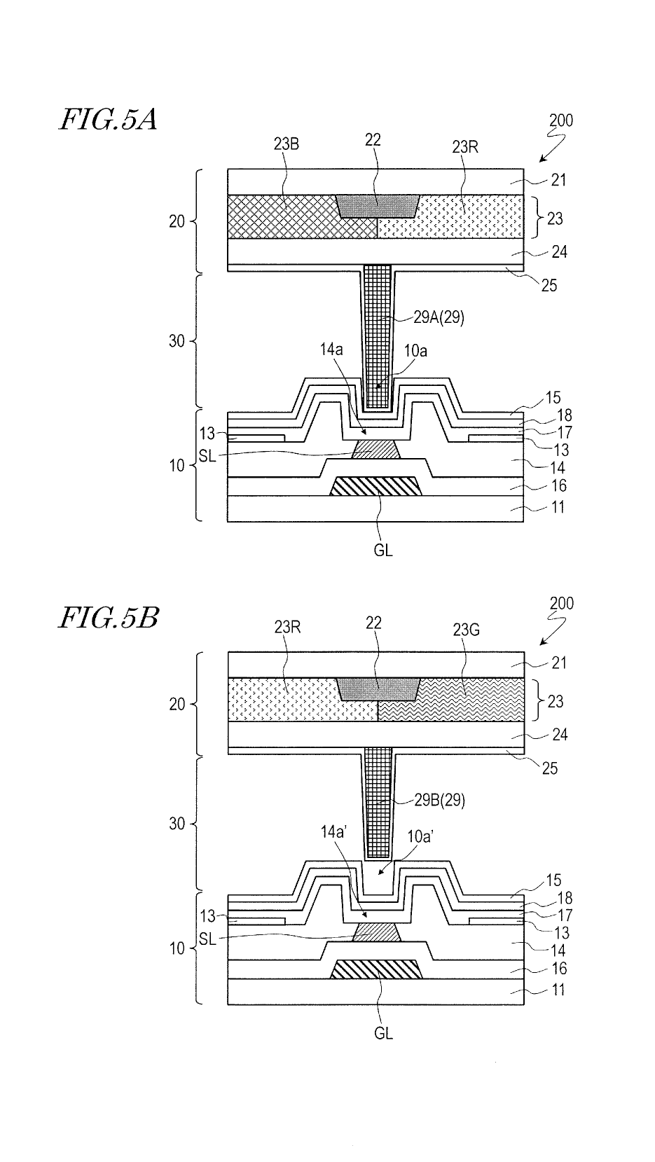

Referring to FIGS. 4, 5A and 5B, a liquid crystal display device 200 of the present embodiment will be described. FIG. 4 is a plan view schematically showing the liquid crystal display device 200. FIGS. 5A and 5B are cross-sectional views schematically showing the liquid crystal display device 200, taken alone line 5A-5A′ and line 5B-5B′, respectively, of FIG. 4. The description below will focus on differences between the liquid crystal display device 200 of the present embodiment and the liquid crystal display device 100 of Embodiment 1.

As shown in FIG. 4, also with the liquid crystal display device 200, as with the liquid crystal display device 100 of Embodiment 1, each of the columnar spacers 29 is arranged in an intersecting region (a region where one of the gate lines GL and one of the source lines SL intersect with each other). As shown in FIG. 5A, also with the liquid crystal display device 200, the first insulating layer 14 has the first opening 14a formed in the intersecting region corresponding to the main spacer 29A, and the distal end portion of the main spacer 29A is located in the depressed portion 10a defined by the first opening 14a.

With the liquid crystal display device 200 of the present embodiment, as shown in FIG. 5B, the first insulating layer 14 has an additional first opening 14a′ formed in each of the intersecting regions corresponding to the sub spacers 29B. The surface of the TFT substrate 10 on the liquid crystal layer 30 side has an additional depressed portion 10a′ defined by the additional first opening 14a′ of the first insulating layer 14 (i.e., reflecting the shape of the additional first opening 14a′). The distal end portion of the sub spacer 29B is aligned with the additional depressed portion 10a′.

When a liquid crystal display device uses main spacers and sub spacers in combination with each other, the sub spacers are shorter in height than the main spacers, and the distal ends of the sub spacers do not come into contact with the TFT substrate. Note however that if the panel surface is pressed to be vertically compressed, the sub spacers come into contact with the TFT substrate. If the panel surface is pressed further, the sub spacers may possibly shift sideways and scratch the alignment film.

With the provision of the additional depressed portion 10a′ in each of the intersecting regions corresponding to the sub spacers 29B as in the present embodiment, when the panel is pressed, it is possible to prevent the sub spacer 29B from shifting sideways and scratching the first alignment film 15 when the panel is pressed because the distal end portion of the sub spacer 29B is fitted into the additional depressed portion 10a′.

Note that in order to maintain the pressure resistance of the panel, it is preferred that the height of the sub spacer 29B is increased by how much the surface of the TFT substrate 10 is depressed (i.e., by the depth of the additional depressed portion 10a′).

Although the cross-sectional structure of the TFT 12 is not shown in the drawings, the liquid crystal display device 200 of the present embodiment also has such a transparent contact structure as described above in Embodiment 1 (this similarly applies to liquid crystal display devices 300, 400, 500 and 600 of Embodiments 3, 4, 5 and 6 to be described later).

### Embodiment 3

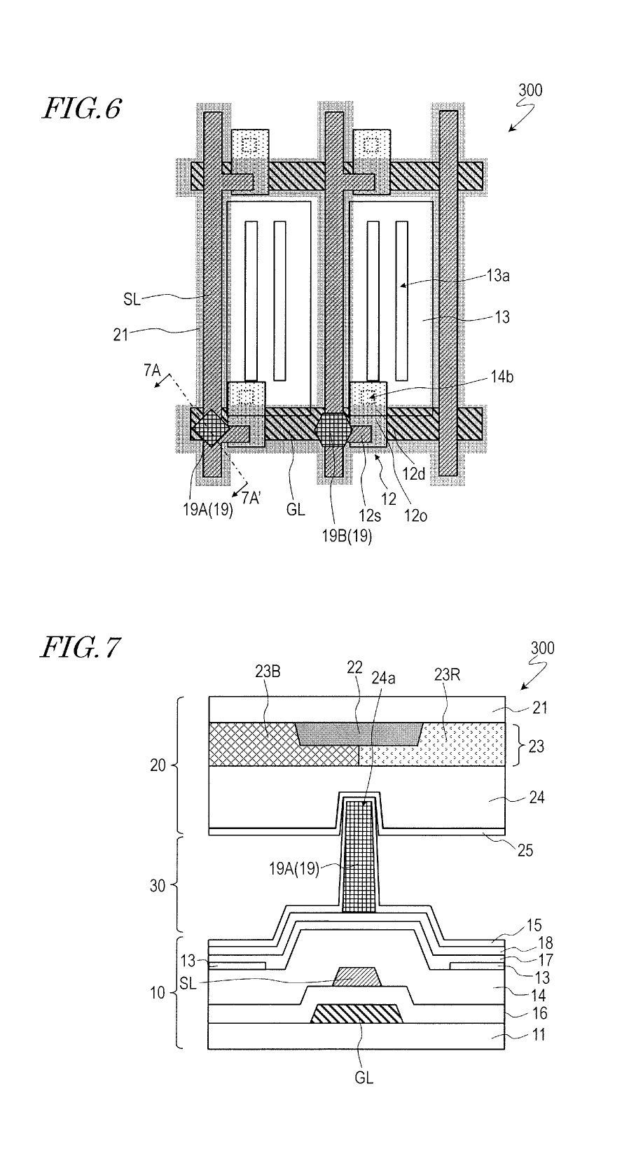

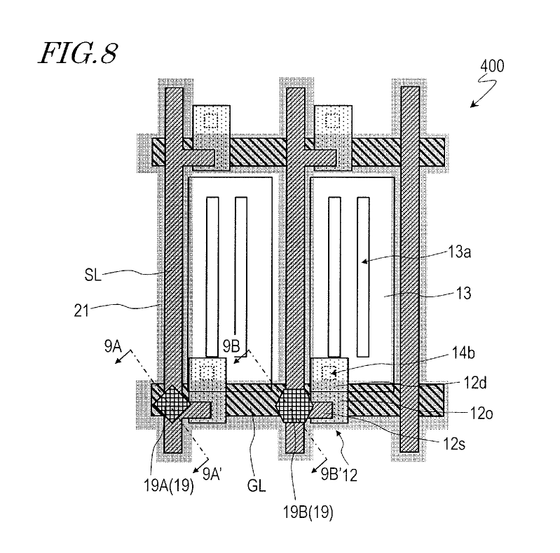

Referring to FIG. 6 and FIG. 7, a liquid crystal display device 300 of the present embodiment will be described. FIG. 6 is a plan view schematically showing the liquid crystal display device 300. FIG. 7 is a cross-sectional view schematically showing the liquid crystal display device 300, taken along line 7A-7A′ of FIG. 6. The description below will focus on differences between the liquid crystal display device 300 of the present embodiment and the liquid crystal display device 100 of Embodiment 1.

The liquid crystal display device 300 of the present embodiment is different from the liquid crystal display device 100 of Embodiment 1 in that the TFT substrate 10, rather than the counter substrate 20, has a plurality of columnar spacers 19 thereon, as shown in FIG. 6 and FIG. 7. The columnar spacers 19 define the thickness of the liquid crystal layer 30. The columnar spacer 19 is arranged in each of the intersecting regions between the gate lines GL and the source lines SL.

The columnar spacers 19 include a plurality of main spacers 19A having a first height, and a plurality of sub spacers 19B having a second height that is smaller than the first height. That is, the columnar spacers 19 include two types of spacers of different heights (the main spacer 19A and the sub spacer 19B).

In the present embodiment, as shown in FIG. 7, the flattening layer 24 has a depressed portion 24a formed in each of the intersecting regions corresponding to the main spacers 19A. The distal end portion of each main spacer 19A is located in the depressed portion 24a (i.e., fitted into the depressed portion 24a). Therefore, it is possible to prevent the main spacer 19A from shifting sideways and scratching the second alignment film 25. Thus, it is possible to set small the width (size) of a portion of the light-blocking layer 22 for shading an area around of the columnar spacer 19, thereby improving the aperture ratio.

Note that the depressed portion 24a of the flattening layer 24 may be a non-through hole as illustrated in FIG. 7 or may be a through hole.

### Embodiment 4

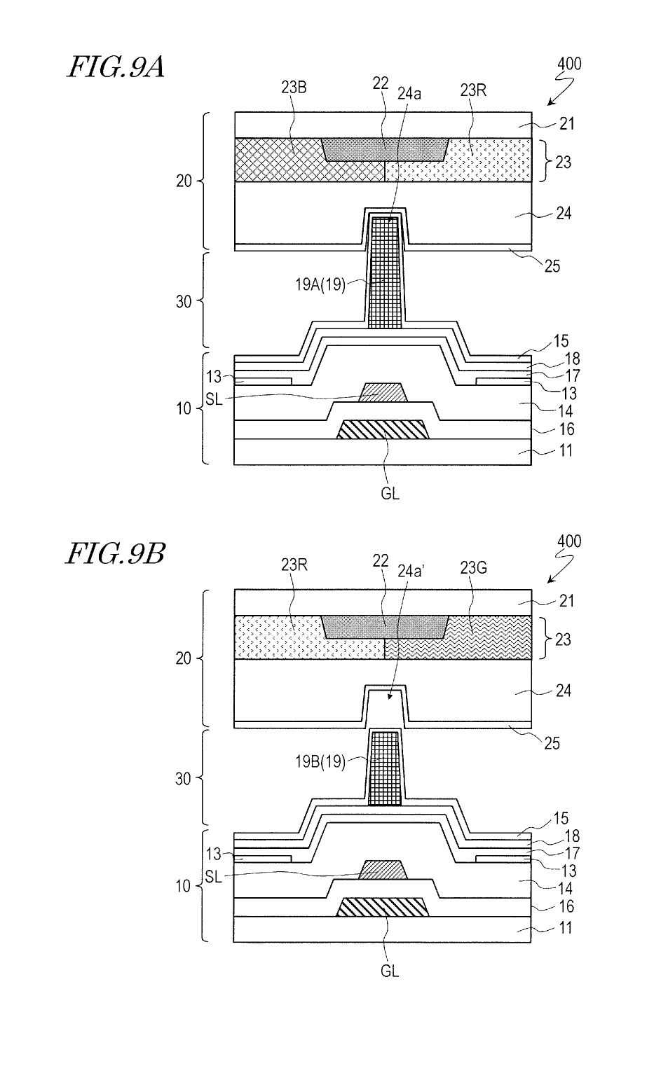

Referring to FIGS. 8, 9A and 9B a liquid crystal display device 400 of the present embodiment will be described. FIG. 8 is a plan view schematically showing the liquid crystal display device 400. FIGS. 9A and 9B are cross-sectional views schematically showing the liquid crystal display device 400, taken alone line 9A-9A′ and line 9B-9B′, respectively, of FIG. 8. The description below will focus on differences between the liquid crystal display device 400 of the present embodiment and the liquid crystal display device 300 of Embodiment 3.

As shown in FIG. 8, also with the liquid crystal display device 400, as with the liquid crystal display device 300 of Embodiment 3, each of the columnar spacers 19 is arranged in an intersecting region (a region where one of the gate lines GL and one of the source lines SL intersect with each other). As shown in FIG. 9A, also with the liquid crystal display device 400, the flattening layer 24 includes the depressed portion 24a formed in the intersecting region corresponding to the main spacer 19A, and the distal end portion of the main spacer 19A is located in the depressed portion 24a.

With the liquid crystal display device 400 of the present embodiment, as shown in FIG. 9B, the flattening layer 24 has an additional depressed portion 24a′ formed in each of the intersecting regions corresponding to the sub spacers 19B. The distal end portion of the sub spacer 19B is aligned with the additional depressed portion 24a′. Therefore, it is possible to prevent the sub spacer 19B from shifting sideways and scratching the second alignment film 25 when the panel is pressed because the distal end portion of the sub spacer 19B is fitted into the additional depressed portion 24a′.

Note that in order to maintain the pressure resistance of the panel, it is preferred that the height of the sub spacer 19B is increased by how much the surface of the counter substrate 20 is depressed (i.e., by the depth of the additional depressed portion 24a′).

### Embodiment 5

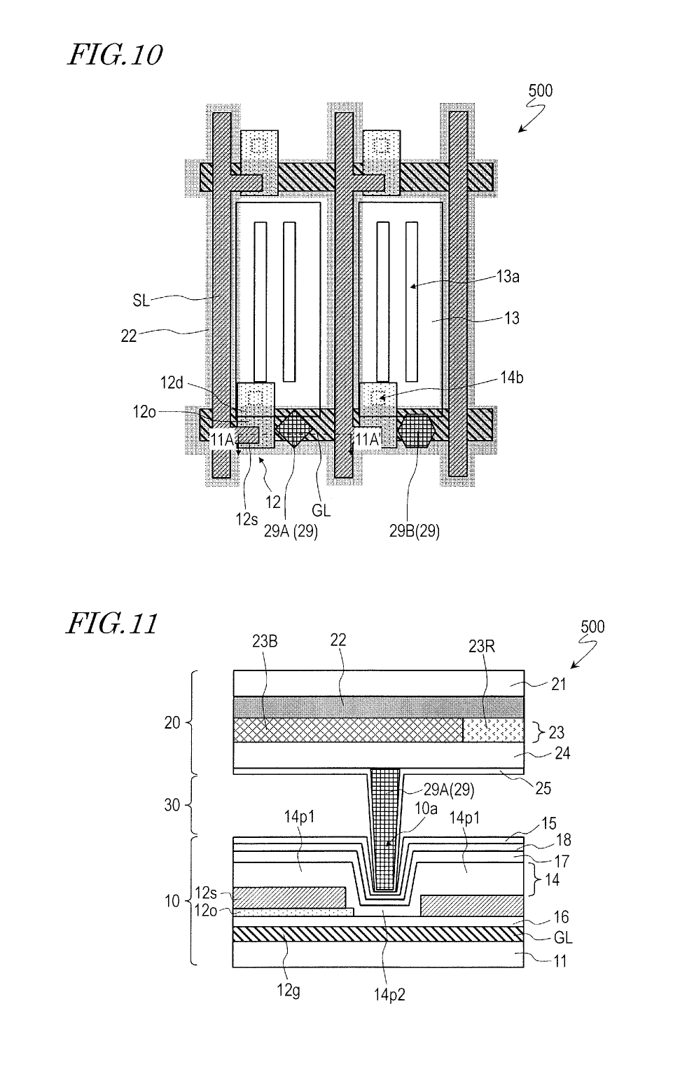

Referring to FIG. 10 and FIG. 11, a liquid crystal display device 500 of the present embodiment will be described. FIG. 10 is a plan view schematically showing the liquid crystal display device 500. FIG. 11 is a cross-sectional view schematically showing the liquid crystal display device 500, taken along line 11A-11A′ of FIG. 10. The description below will focus on differences between the liquid crystal display device 500 of the present embodiment and the liquid crystal display device 100 of Embodiment 1.

The liquid crystal display device 500 of the present embodiment is different from the liquid crystal display device 100 of Embodiment 1 in that each of the columnar spacers 29 is not arranged in an intersecting region (a region where one of the gate lines GL and one of the source lines SL intersect with each other).

With the liquid crystal display device 500, as shown in FIG. 10, each columnar spacer 29 is located between two adjacent ones of the source lines SL (i.e., arranged so as not to be aligned with source lines SL). As shown in FIG. 11, each columnar spacer 29 is arranged so as to be aligned with one of the gate lines GL and not aligned with the source electrode 12s.

As shown in FIG. 11, the first insulating layer 14 includes a first portion 14p1 that covers the source lines SL and the source electrodes 12s (i.e., that is located directly above the source lines SL and the source electrodes 12s), and a second portion 14p2 that does not cover the source lines SL and the source electrodes 12s (i.e., that is not located directly above the source lines SL and the source electrodes 12s). The second portion 14p2 of the first insulating layer 14 is depressed relative to the first portion 14p1 because of the absence of the source lines SL and the source electrodes 12s thereunder.

The surface of the TFT substrate 10 on the liquid crystal layer 30 side has the depressed portions 10a, each defined by the second portion 14p2 of the first insulating layer 14, located corresponding to the main spacers 29A. The distal end portion of the main spacer 29A is located in the depressed portion 10a (i.e., fitted into the depressed portion 10a). Therefore, it is possible to prevent the main spacer 29A from shifting sideways and scratching the first alignment film 15.

Note that with the liquid crystal display device 500 of the present embodiment, the main spacers 29A are prevented from shifting along the row direction (the direction in which the gate lines GL extend), but it is difficult to prevent the main spacers 29A from shifting along the column direction (the direction in which the source line SL extend). Thus, it can be said that the configuration of the liquid crystal display device 100 of Embodiment 1 is preferred in order to more reliably prevent the main spacers 29A from shifting.

### Embodiment 6

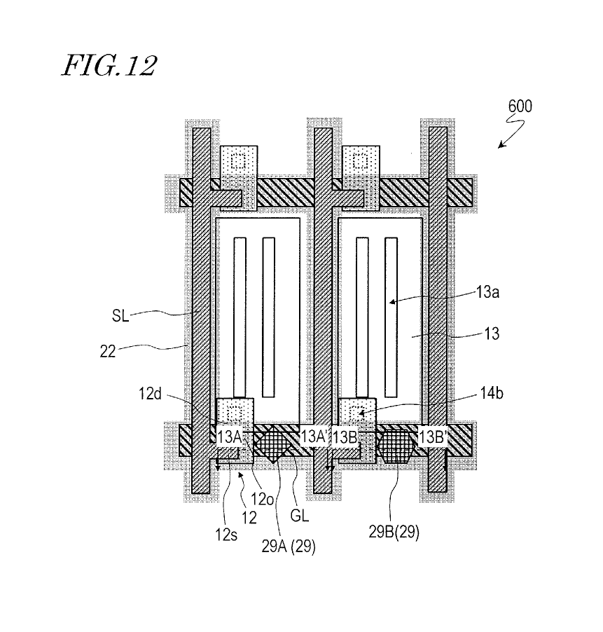

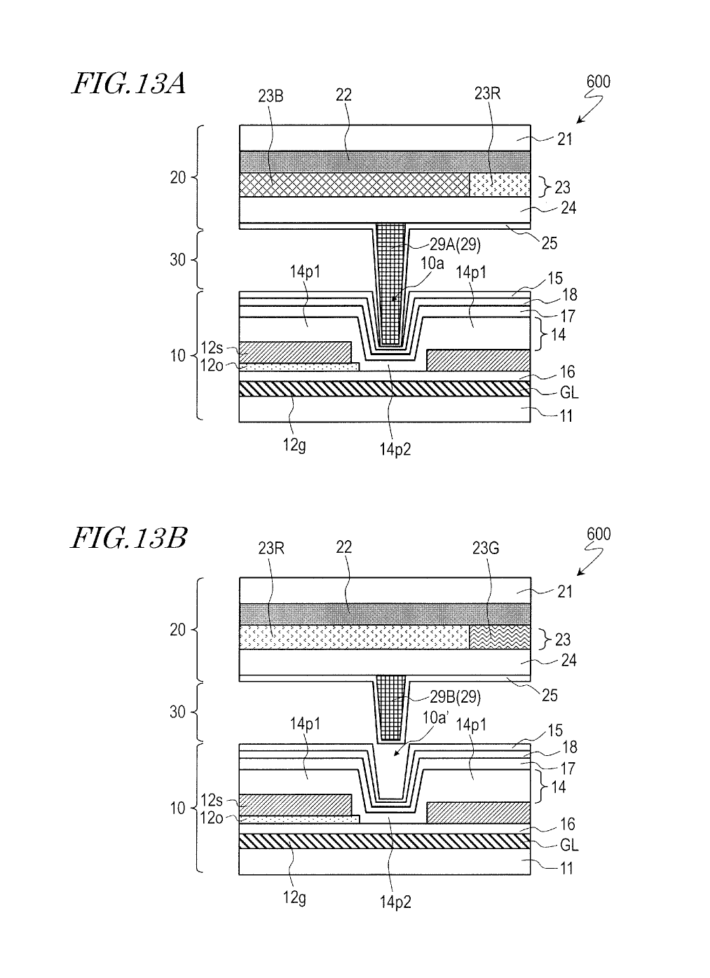

Referring to FIGS. 12, 13A and 13B, a liquid crystal display device 600 of the present embodiment will be described. FIG. 12 is a plan view schematically showing the liquid crystal display device 600. FIGS. 13A and 13B are cross-sectional views schematically showing the liquid crystal display device 600, taken alone line 13A-13A′ and line 13B-13B′, respectively, of FIG. 12. The description below will focus on differences between the liquid crystal display device 600 of the present embodiment and the liquid crystal display device 500 of Embodiment 5.

As shown in FIG. 12, also with the liquid crystal display device 600, as with the liquid crystal display device 500 of Embodiment 5, each of the columnar spacers 29 is located between two adjacent source lines SL. As shown in FIG. 13A, also with the liquid crystal display device 600, the surface of the TFT substrate 10 on the liquid crystal layer 30 side has the depressed portions 10a, each defined by the second portion 14p2 of the first insulating layer 14, located corresponding to the main spacers 29A. The distal end portion of the main spacer 29A is located in the depressed portion 10a.

With the liquid crystal display device 600 of the present embodiment, as shown in FIG. 13B, the surface of the TFT substrate 10 on the liquid crystal layer 30 side has the additional depressed portions 10a′, each defined by the second portion 14p2 of the first insulating layer 14, located corresponding to the sub spacers 29B. The distal end portion of the sub spacer 29B is aligned with the additional depressed portion 10a′. Therefore, it is possible to prevent the sub spacer 29B from shifting sideways and scratching the first alignment film 15 when the panel is pressed because the distal end portion of the sub spacer 29B is fitted into the additional depressed portion 10a′.

Note that in order to maintain the pressure resistance of the panel, it is preferred that the height of the sub spacer 29B is increased by the depth of the additional depressed portion 10a′.

<Regarding Oxide Semiconductor>

The oxide semiconductor included in the oxide semiconductor layer 12o may be an amorphous oxide semiconductor or a crystalline oxide semiconductor having a crystalline portion. Examples of the crystalline oxide semiconductor include a polycrystalline oxide semiconductor, a microcrystalline oxide semiconductor, and a crystalline oxide semiconductor whose c-axis is oriented generally perpendicular to the layer surface.

The oxide semiconductor layer 12o may have a layered structure including two or more layers. When the oxide semiconductor layer 12o has a layered structure, the oxide semiconductor layer 12o may include a non-crystalline oxide semiconductor layer and a crystalline oxide semiconductor layer. Alternatively, it may include a plurality of crystalline oxide semiconductor layers having different crystalline structures. It may include a plurality of non-crystalline oxide semiconductor layers. When the oxide semiconductor layer 12o has a two-layer structure including an upper layer and a lower layer, it is preferred that the energy gap of the oxide semiconductor included in the upper layer is greater than the energy gap of the oxide semiconductor included in the lower layer. Note however that when the energy gap difference between these layers is relatively small, the energy gap of the oxide semiconductor of the lower layer may be greater than the energy gap of the oxide semiconductor of the upper layer.

The material, the structure, the film formation method of the non-crystalline oxide semiconductor and each of the crystalline oxide semiconductors, and the configuration of an oxide semiconductor layer having a layered structure, etc., are described in Japanese Laid-Open Patent Publication No. 2014-007399, for example. The disclosure of Japanese Laid-Open Patent Publication No. 2014-007399 is herein incorporated by reference in its entirety.

The oxide semiconductor layer 12o may at least include one metal element from among In, Ga and Zn, for example. In an embodiment of the present invention, the oxide semiconductor layer 12o includes an In—Ga—Zn—O-based semiconductor (e.g., indium gallium zinc oxide), for example. Now, the In—Ga—Zn—O-based semiconductor is a ternary oxide of In (indium), Ga (gallium) and Zn (zinc), and there is no particular limitation on the ratio (composition ratio) between In, Ga and Zn, examples of which include In:Ga:Zn=2:2:1, In:Ga:Zn=1:1:1 and In:Ga:Zn=1:1:2, for example. Such an oxide semiconductor layer 12o can be formed from an oxide semiconductor film including an In—Ga—Zn—O-based semiconductor. Note that a channel-etched type TFT having an active layer including an oxide semiconductor such as an In—Ga—Zn—O-based semiconductor is in some cases referred to as a “CE-OS-TFT”.

The in-Ga—Zn—O-based semiconductor may be amorphous or crystalline. The crystalline In—Ga—Zn—O-based semiconductor is preferably a crystalline In—Ga—Zn—O-based semiconductor whose c-axis is oriented generally perpendicular to the layer surface.

Note that crystalline structures of crystalline In—Ga—Zn—O-based semiconductors are disclosed in, for example, Japanese Laid-Open Patent Publication No. 2014-007399, supra, Japanese Laid-Open Patent Publication No. 2012-134475, Japanese Laid-Open Patent Publication No. 2014-209727, etc. The disclosures of Japanese Laid-Open Patent Publication No. 2012-134475 and Japanese Laid-Open Patent Publication No. 2014-209727 are herein incorporated by reference in their entirety. Since TFTs including an In—Ga—Zn—O-based semiconductor layer have a high mobility (more than 20 times that of an a-SiTFT) and a low leak current (less than 1/100 that of an a-SiTFT), they can desirably be used as driver TFTs (e.g., TFTs included in driver circuits provided around the display region including a plurality of pixels and on the same substrate as the display region) and pixel TFTs (TFTs provided in pixels).

The oxide semiconductor layer 12o may include another oxide semiconductor instead of an In—Ga—Zn—O-based semiconductor. For example, it may include an In—Sn—Zn—O-based semiconductor (e.g., In₂O₃—SnO₂—ZnO; InSnZnO). The In—Sn—Zn—O-based semiconductor is a ternary oxide of In (indium), Sn (tin) and Zn (zinc). Alternatively, the oxide semiconductor layer 12o may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), an Mg—Zn—O-based semiconductor, an In—Ga—Sn—O-based semiconductor, an In—Ga—O-based semiconductor, a Zr—In—Zn—O-based semiconductor, an Hf—In—Zn—O-based semiconductor, or the like.

Note that the TFT 12, which is an oxide semiconductor TFT, may be a “channel-etched-type TFT” or an “etch stop-type TFT”.

With a “channel-etched-type TFT”, as shown in FIG. 2B, for example, no etch stop layer is formed over the channel region, and the lower surface of the channel-side end portion of the source and drain electrode is arranged to be in contact with the upper surface of the oxide semiconductor layer.

On the other hand, with a TFT including an etch stop layer formed over the channel region (an etch stop-type TFT), the lower surface of the channel-side end portion of the source and drain electrode is located on the etch stop layer, for example.

According to embodiments of the present invention, it is possible to improve the aperture ratio of liquid crystal display devices having oxide semiconductor TFTs. Liquid crystal display devices according to embodiments of the present invention have high aperture ratios and can therefore be desirably applicable to various applications.

This application is based on Japanese Patent Application No. 2017-235867 filed on Dec. 8, 2017, the entire contents of which are hereby incorporated by reference.

What is claimed is:

1. A liquid crystal display device, comprising:
a first substrate;
a second substrate opposing the first substrate; and
a liquid crystal layer provided between the first substrate and the second substrate, wherein:
the liquid crystal display device includes a plurality of pixels arranged in a matrix pattern having rows and columns;
the first substrate includes a plurality of gate lines each extending in a row direction, a plurality of source lines each extending in a column direction, a TFT provided in each of the pixels, a pixel electrode provided in each of the pixels, a first insulating layer covering the source lines, and a first alignment film provided so as to be in contact with the liquid crystal layer;
the second substrate includes a light-blocking layer arranged so as to be aligned with the gate lines and the source lines, a plurality of columnar spacers defining a thickness of the liquid crystal layer, and a second alignment film provided so as to be in contact with the liquid crystal layer;
the TFT includes a gate electrode, a source electrode, a drain electrode, and an oxide semiconductor layer;
the pixel electrode is electrically connected to the drain electrode of the TFT;
the drain electrode is a transparent drain electrode formed from the same transparent conductive film as the pixel electrode;
each of the columnar spacers is arranged in an intersecting region where one of the gate lines and one of the source lines intersect with each other;
the first insulating layer has first openings formed in the intersecting regions corresponding to at least some of the columnar spacers;
a surface of the first substrate on a side of the liquid crystal layer has depressed portions that are defined by the first openings; and
distal end portions of the at least some of the columnar spacers are located in the depressed portions.

2. The liquid crystal display device according to claim 1, wherein:
the columnar spacers include a plurality of main spacers having a first height, and a plurality of sub spacers having a second height that is smaller than the first height; and
the at least some of the columnar spacers are the main spacers.

3. The liquid crystal display device according to claim 2, wherein:
the first insulating layer has an additional first opening formed in each of the intersecting regions corresponding to the sub spacers;
a surface of the first substrate on a side of the liquid crystal layer has an additional depressed portion defined by the additional first opening; and
distal end portions of the sub spacers are aligned with the additional depressed portions.

4. The liquid crystal display device according to claim 1, wherein:
the oxide semiconductor layer is provided on the gate electrode with a gate insulating layer interposed therebetween;
the oxide semiconductor layer and the source electrode are covered by the first insulating layer;
the first insulating layer has a second opening through which a portion of the oxide semiconductor layer is exposed; and
the transparent drain electrode is connected to the oxide semiconductor layer through the second opening.

5. A liquid crystal display device, comprising:
a first substrate;
a second substrate opposing the first substrate; and
a liquid crystal layer provided between the first substrate and the second substrate, wherein:
the liquid crystal display device includes a plurality of pixels arranged in a matrix pattern having rows and columns;
the first substrate includes a plurality of gate lines each extending in a row direction, a plurality of source lines each extending in a column direction, a TFT provided in each of the pixels, a pixel electrode provided in each of the pixels, a plurality of columnar spacers defining a thickness of the liquid crystal layer, and a first alignment film provided so as to be in contact with the liquid crystal layer;
the second substrate includes a light-blocking layer arranged so as to be aligned with the gate lines and the source lines, a color filter layer, a flattening layer covering the color filter layer, and a second alignment film provided so as to be in contact with the liquid crystal layer;
the TFT includes a gate electrode, a source electrode, a drain electrode, and an oxide semiconductor layer;
the pixel electrode is electrically connected to the drain electrode of the TFT;
the drain electrode is a transparent drain electrode formed from the same transparent conductive film as the pixel electrode;
each of the columnar spacers is arranged in an intersecting region where one of the gate lines and one of the source lines intersect with each other;
the flattening layer has depressed portions formed in the intersecting regions corresponding to at least some of the columnar spacers; and
distal end portions of the at least some of the columnar spacers are located in the depressed portions.

6. The liquid crystal display device according to claim 5, wherein:
the columnar spacers include a plurality of main spacers having a first height, and a plurality of sub spacers having a second height that is smaller than the first height; and
the at least some of the columnar spacers are the main spacers.

7. The liquid crystal display device according to claim 6, wherein:
the flattening layer has additional depressed portions formed in the intersecting regions corresponding to sub spacers; and
distal end portions of the sub spacers are aligned with the additional depressed portions.

8. The liquid crystal display device according to claim 5, wherein:
the first substrate further includes a first insulating layer covering the source lines;
the oxide semiconductor layer is provided on the gate electrode with a gate insulating layer interposed therebetween;
the oxide semiconductor layer and the source electrode are covered by the first insulating layer;
the first insulating layer has an opening through which a portion of the oxide semiconductor layer is exposed; and
the transparent drain electrode is connected to the oxide semiconductor layer through the opening.

9. A liquid crystal display device, comprising:
a first substrate;
a second substrate opposing the first substrate; and
a liquid crystal layer provided between the first substrate and the second substrate, wherein:
the liquid crystal display device includes a plurality of pixels arranged in a matrix pattern having rows and columns;
the first substrate includes a plurality of gate lines each extending in a row direction, a plurality of source lines each extending in a column direction, a TFT provided in each of the pixels, a pixel electrode provided in each of the pixels, a first insulating layer provided on the source lines, and a first alignment film provided so as to be in contact with the liquid crystal layer;
the second substrate includes a light-blocking layer arranged so as to be aligned with the gate lines and the source lines, a plurality of columnar spacers defining a thickness of the liquid crystal layer, and a second alignment film provided so as to be in contact with the liquid crystal layer;
the TFT includes a gate electrode, a source electrode, a drain electrode, and an oxide semiconductor layer;
the pixel electrode is electrically connected to the drain electrode of the TFT;
the drain electrode is a transparent drain electrode formed from the same transparent conductive film as the pixel electrode;
each of the columnar spacers is located between two adjacent ones of the source lines and is arranged so as to be aligned with one of the gate lines while not aligned with the source electrodes;
the first insulating layer includes a first portion that covers the source lines and the source electrodes, and a second portion that does not cover the source lines and the source electrodes and that is depressed relative to the first portion;
a surface of the first substrate on a side of the liquid crystal layer has a depressed portion that is defined by the second portion of the first insulating layer and is provided at each of positions corresponding to at least some of the columnar spacers; and
distal end portions of the at least some of the columnar spacers are located in the depressed portions.

10. The liquid crystal display device according to claim 9, wherein:
the columnar spacers include a plurality of main spacers having a first height, and a plurality of sub spacers having a second height that is smaller than the first height; and
the at least some of the columnar spacers are the main spacers.

11. The liquid crystal display device according to claim 10, wherein:
a surface of the first substrate on a side of the liquid crystal layer has an additional depressed portion that is defined by the second portion of the first insulating layer and is provided at each of positions corresponding to the sub spacers; and
distal end portions of the sub spacers are aligned with the additional depressed portions.

12. The liquid crystal display device according to claim 9, wherein:
the oxide semiconductor layer is provided on the gate electrode with a gate insulating layer interposed therebetween;
the oxide semiconductor layer is covered by the first insulating layer;
the first insulating layer has an opening through which a portion of the oxide semiconductor layer is exposed; and
the transparent drain electrode is connected to the oxide semiconductor layer through the opening.

13. The liquid crystal display device according to claim 1, wherein the first substrate further includes a second insulating layer covering the pixel electrode, and a common electrode provided on the second insulating layer.

14. The liquid crystal display device according to claim 1, wherein the oxide semiconductor layer includes an In—Ga—Zn—O-based semiconductor.

15. The liquid crystal display device according to claim 14, wherein the In—Ga—Zn—O-based semiconductor includes a crystalline portion.
